(19) United States
(12) Patent Application Publication
(10) Pub. No.: US 2010/0176807 A1
(43) Pub. Date: Jul. 15, 2010

(54) MAGNETIC SENSOR DEVICE

(75) Inventors: Haris Duric, Helmond (NL); Josephus Arnoldus Henricus Maria Kahlman, Tilburg (NL); Bart Michiel De Boer, Den Bosch (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/377,219

(22) PCT Filed: Aug. 7, 2007
(86) PCT No.: PCT/IB07/53117

§ 371 Date: Feb. 11, 2009

(30) Foreign Application Priority Data
Aug. 15, 2006 (EP) 06118917.1

(51) Int. Cl. G01R 33/12

(52) U.S. Cl. 324/228

(57) ABSTRACT

The present invention provides a magnetic sensor device (20) comprising at least one sensor surface lying in a first plane, a first magnetic field generating means (12) for attracting magnetic or magnetizable objects (15) toward a sensor surface (13), the first magnetic field generating means (12) lying in a second plane different from and substantially parallel to the first plane, and a second magnetic field generating means (14) for magnetizing magnetic or magnetizable objects (15) which are bond to the sensor. The spacing between the first magnetic field generating means (12) and the at least one sensor element (11) is smaller than 2 μm down to optionally overlapping. The present invention furthermore provides a method for determining the presence and/or amount of magnetic or magnetizable objects (15) in a sample fluid using the magnetic sensor device (20) according to embodiments of the invention.

The present invention relates to magnetic sensors and more particular relates to attraction of magnetic or magnetizable objects towards sensitive area of the magnetic sensor. The present invention furthermore relates to a method for detecting and/or quantifying magnetic or magnetizable objects in a sample fluid. The magnetic sensor device and method according to the present invention may be used in molecular diagnostics, biological sample analysis or chemical sample analysis.

Magnetic sensors based on AMR (anisotropic magneto resistance), GMR (giant magneto resistance) and TMR (tunnel magneto resistance) elements or on Hall sensors, are nowadays gaining importance. Besides the known high-speed applications such as magnetic hard disk heads and MRAM, new relatively low bandwidth applications appear in the field of molecular diagnostics (MDx), current sensing in IC's, automotive, etc.

The introduction of micro-arrays or biochips comprising such magnetic sensors is revolutionising the analysis of biomolecules such as DNA (desoxyribonucleic acid), RNA (ribonucleic acid) and proteins. Applications are, for example, human genotyping (e.g. in hospitals or by individual doctors or nurses), bacteriological screening, biological and pharmacological research. Such magnetic biochips have promising properties for, for example, biological or chemical sample analysis, in terms of sensitivity, specificity, integration, ease of use and costs.

Biochips, also called biosensor chips, biological microchips, gene-chips or DNA chips, consist in their simplest form of a substrate on which a large number of different probe molecules are attached, on well defined regions on the chip, to which molecules or molecule fragments that are to be analysed can bind if they are perfectly matched. For example, a fragment of a DNA molecule binds to one unique complementary DNA (c-DNA) molecular fragment. The occurrence of a binding reaction can be detected, for example by using markers, e.g. fluorescent markers or magnetic labels, that are coupled to the molecules to be analysed. This provides the ability to analyse small amounts of a large number of different molecules or molecular fragments in parallel, in a short time.

In a biosensor an assay takes place. Assays generally involve several fluid actuation steps, i.e. steps in which materials are brought into movement. Examples of such steps are mixing (e.g. for dilution, or for the dissolution of labels or other reagents into the sample fluid, or labelling, or affinity binding) or the refresh of fluid near to a reaction surface in order to avoid that diffusion becomes rate-limiting for the reaction. Preferably the actuation method should be effective, reliable and cheap.

One biochip can hold assays for 1000 or more different molecular fragments. It is expected that the usefulness of information that can become available from the use of biochips will increase rapidly during the coming decade, as a result of projects such as the Human Genome Project, and follow-up studies on the functions of genes and proteins.

A biosensor consisting of an array of, for example 100, sensors based on the detection of e.g. superparamagnetic beads may be used to simultaneously measure the concentration of a large number of different biological molecules (e.g. protein, DNA) in a solution (e.g. blood). This may be achieved by attaching a superparamagnetic bead to target molecules which are to be determined, magnetizing this bead with an applied magnetic field and using e.g. a Giant Magneto Resistance (GMR) sensor to detect the magnetic field of the magnetized beads.

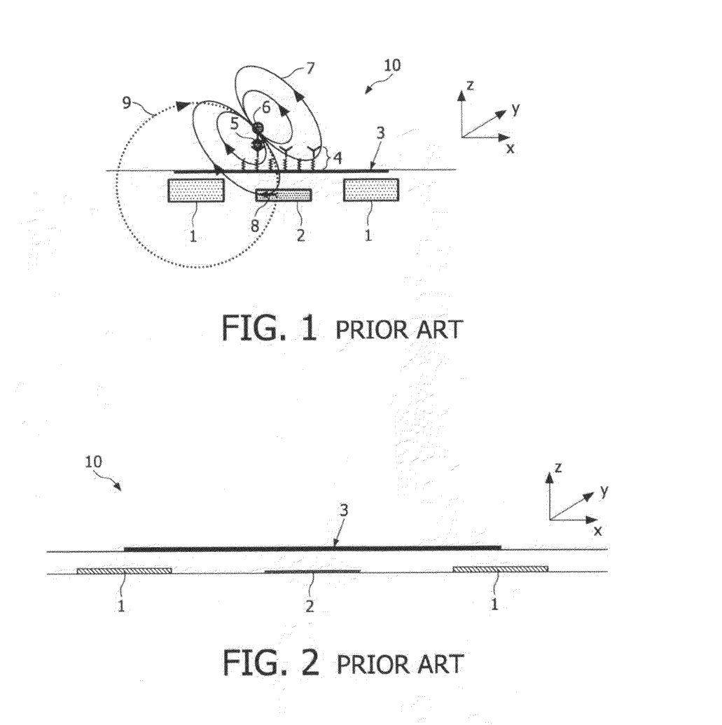

FIG. 1 illustrates a magnetoresistive sensor 10 with integrated magnetic field excitation. With integrated magnetic field excitation is meant that a magnetic field generating means is integrated in the magnetoresistive sensor 10. The magnetoresistive sensor 10 comprises two electric conductors 1 which form the magnetic field generating means and a GMR element 2 which forms a magnetoresistive sensor element. At the surface 3 of the magnetoresistive sensor 10, binding sites 4 are provided to which, for example, target molecules 5 with attached thereto a magnetic nanoparticle 6, can bind. A current flowing through the conductors 1 generates a magnetic field which magnetizes the magnetic nanoparticle 6. The magnetic nanoparticle 6 develops a magnetic moment m indicated by field lines 7 in FIG. 1. The magnetic moment m then generates dipolar magnetic fields, which have in-plane magnetic field components 8 at the location of the GMR element 2. Thus, the magnetic nanoparticle 6 deflects the magnetic field 9 induced by the current through the conductor 1, resulting in the magnetic field component in the sensitive x-direction (indicated by reference number 8 in FIG. 1) of the GMR element 2, also called x-component of the magnetic field Hₑₓₜ. The x-component of the magnetic field Hₑₓ, is then sensed by the GMR element 2 and depends on the number Nₙₚ of magnetic nanoparticles 6 present at the surface 3 of the magnetoresistive sensor 10 and on the magnitude of the conductor current.

FIG. 2 shows a cross-sectional view of a sensor device 10 according to the prior art. It comprises a GMR sensor element 2 and two conductors 1. When a current is sent through the conductors 1, magnetic particles 6 are attracted toward the sensor surface 3 to the locations above the conductors 1.

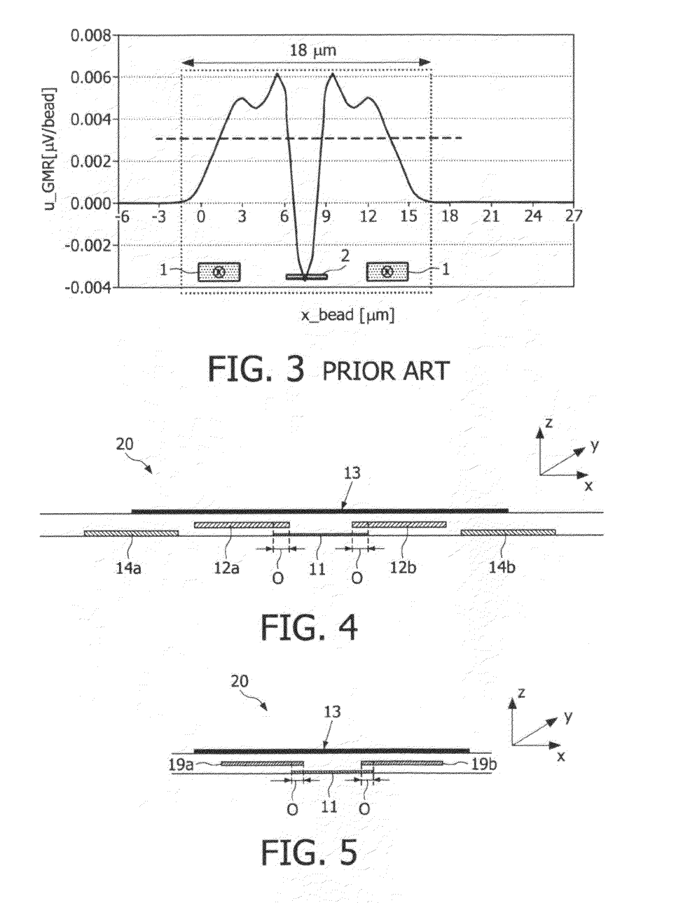

FIG. 3 illustrates the signal of the GMR sensor element 2 per magnetic particle 6 as a function of the x-position of the magnetic particle on the sensor surface 3 in case of 200 nm Ademtech particles, for a GMR sensor element 2 with a length l of 100 μm and a sensitivity of s_{GMR}=0.003 Ωm/A and for Iwire,1=80 mAₚₚ, Iwire,2=80 mAₚₚ and Iₛₑₙₛₑ=2.4 mAₚₚ. It can be seen from this figure that the GMR sensor element 2 has a highest signal of between 0.0045 and 0.006 μV/particle is obtained at the edges of the GMR sensor element 2 and in between the GMR sensor element 2 and the conductors 1. The dashed line in FIG. 3 indicates the average signal measured by the GMR sensor element 2 which is about 2.8 nV/particle.

Magnetic particles 6 are attracted to locations at the sensor surface 3 different from the locations where the sensitive of the GMR sensor element 2 is the highest. Therefore, full capacity of the GMR sensor element 2 cannot be used.

It is an object of the present invention to provide a good magnetic sensor device and method for detecting and/or quantifying magnetic or magnetizable objects in a sample fluid using the magnetic sensor device according to embodiments of the invention.

The magnetic sensor device and method according to embodiments of the invention shows good sensitivity and can be used for detecting and/or quantifying low amounts of target moieties in a sample fluid.

The magnetic sensor device and method according to the present invention may be used in molecular diagnostics, biological sample analysis or chemical sample analysis.

The above objective is accomplished by a device and method according to the present invention. A particular feature of the present invention is that the spacing between the magnetic field generating means and the sensor element is smaller than the minimum feature size, i.e. smaller than the minimal process limit for spacing between features lying in a same plane, e.g. smaller than 2 micron down to optionally overlapping, the spacing being the distance between the magnetic field generating means and the sensor element defined by a normal projection of the first magnetic field generating means onto the plane of the sensor element.

Particular and preferred aspects of the invention are set out in the accompanying independent and dependent claims. Features from the dependent claims may be combined with features of the independent claims and with features of other dependent claims as appropriate and not merely as explicitly set out in the claims.

In a first aspect, the present invention provides a magnetic sensor device having a surface and comprising:
at least one sensor element for sensing the presence of magnetic or magnetizable objects, the at least one sensor element lying in a first plane,
first magnetic field generating means for generating a first magnetic field, the first magnetic field being for attracting magnetic or magnetizable objects toward the sensor surface, and
second magnetic field generating means for generating a second magnetic field, the second magnetic field being for magnetizing the magnetic or magnetizable objects,
the first magnetic field generating means lying in a second plane different from and substantially parallel to the first plane,
wherein the spacing between the first magnetic field generating means and the sensor element is smaller than 2 micron down to optionally overlapping, the spacing being the distance between the first magnetic field generating means and the sensor element defined by projection of the first magnetic field generating means onto the plane of the sensor element according to a direction substantially perpendicular to the first and second plane.

An advantage of the magnetic sensor device according to embodiments of the invention is that the first magnetic field generating means for attracting magnetic or magnetizable objects, e.g. magnetic particles, to the sensor surface is still electrically isolated from the sample fluid but provides a possibility to attract magnetic or magnetizable objects, e.g. magnetic particles, to the most sensitive locations of the magnetic sensor device, hereby increasing the sensitivity of the magnetic sensor device.

According to most preferred embodiments of the invention, the first magnetic field generating means may be located in between the first plane and the sensor surface.

An advantage hereof is that the first magnetic field generating means is located close to the sensor surface and thus lower currents are to be sent through the first magnetic field generating means for generating a magnetic field strong enough to attract magnetic or magnetizable objects, e.g. magnetic particles, to the sensor surface.

The first magnetic field may have a first frequency and a first phase and the second magnetic field may have a second frequency and a second phase.

According to embodiments of the invention, the first frequency may be different from the second frequency and/or the first phase may be different from the second phase.

An advantage hereof is that attracting and detection/quantifying magnetic or magnetizable objects, e.g. magnetic particles, may be performed simultaneously.

According to embodiments of the invention, the first magnetic field generating means may have an overlap with the sensor element, the overlap being defined by the projection of the first magnetic field generating means onto the sensor element in a direction substantially perpendicular to the first and second plane. The overlap may be between 0 μm and 1 μm or between 0 μm and 0.5 μm.

According to other embodiments of the invention, the first magnetic field generating means and the sensor element may show no overlap. In these cases, the distance between the first magnetic field generating means and the sensor element may be smaller than the minimum feature size or the minimal process limit for spacing between features lying in a same plane, which is according to current techniques about 2 μm. Preferably, the distance between the first magnetic field generating means and the sensor element may be smaller than 1 μm.

According to embodiments of the invention, the first magnetic field generating means and the second magnetic field generating means may be joined in a same combined magnetic field generating means.

An advantage hereof is that when the sensor element is repeated across a sensor chip, or in other words, when the magnetic sensor device comprises a plurality of magnetic sensor elements, the sensor elements can be placed closer to each other and thus the sensor device may comprise more sensitive area for binding and measuring particles. This may further increase the sensitivity of the magnetic sensor device.

According to embodiments of the invention, the second magnetic field generating means may lie in the same first plane as the at least one sensor element.

According to these embodiments, the first and second magnetic field generating means may be different from each other. An advantage hereof is that actuation or attraction and detection/quantifying of magnetic or magnetizable objects, e.g. magnetic particles, is separated. Because attraction and detection of magnetizable objects, e.g. magnetic particles, is done by separated magnetic field generating means, attraction and detection may be performed simultaneously. In these cases, the first magnetic field generating means may generate a first magnetic field with a first frequency for attracting magnetizable objects, e.g. magnetic particles, toward the sensor surface and the second magnetic field generating means may generate a second magnetic field with a second frequency for detecting magnetizable objects, e.g. magnetic particles, which have bond to the sensor surface, the second frequency being different from the first frequency.

The magnetic sensor device may, according to embodiments of the invention, furthermore comprise a third magnetic field generating means lying in a third plane substantially parallel to the first and second plane, the third plane being located such that the distance between the sensor surface and the third plane is larger than the distance between the sensor surface and the second plane.

An advantage hereof is that magnetic cross-talk may be reduced in that way.

According to embodiments of the present invention, the second magnetic field generating means may be an on-chip or integrated magnetic field generating means. According to other embodiments of the invention, the second magnetic field generating means may be an off-chip or external magnetic field generating means.

In a second aspect according to the present invention, a biochip is provided comprising at least one magnetic sensor device according to embodiments of the present invention.

The present invention also provides the use of the magnetic sensor device according to embodiments of the present invention in molecular diagnostics, biological sample analysis or chemical sample analysis.

The present invention also provides the use of the biochip according to embodiments of the present invention in molecular diagnostics, biological sample analysis or chemical sample analysis.

In a further aspect of the present invention, a method is provided for determining the presence and/or amount of magnetic or magnetizable objects in a sample fluid, the method comprising:
providing the sample fluid to a surface of a magnetic sensor device according to embodiments of the present invention,
applying a first magnetic field having a first frequency for attracting the magnetic or magnetizable objects toward the sensor surface,
applying a second magnetic field having a second frequency for magnetizing the magnetic or magnetizable objects, the second frequency being different from the first frequency or the second phase being different from the first phase,
measuring a magnetic field in a sensitive layer of the at least one sensor element,
in the measured magnetic field discriminating between a first component emanating from the first magnetic field and a second component emanating from the second magnetic field, based on frequencies, and
determining the presence and/or amount of magnetic or magnetizable objects from the second component.

The present invention also provides a method for determining the presence and/or amount of magnetic or magnetizable objects in a sample fluid, the method comprising:
providing the sample fluid to a surface of a magnetic sensor device according to embodiments of the present invention,
applying a first magnetic field having a first frequency and a first phase for attracting the magnetic or magnetizable objects toward the sensor surface,
applying a second magnetic field having a second frequency and a second phase for magnetizing the magnetic or magnetizable objects, the second frequency being different from the first frequency or the second phase being different from the first phase,
measuring a magnetic field in a sensitive layer of the at least one sensor element,
in the measured magnetic field discriminating between a first component emanating from the first magnetic field and a second component emanating from the second magnetic field, based on frequency and/or phase differences, and
determining the presence and/or amount of magnetic or magnetizable objects from the second component.

According to preferred embodiments of the invention, applying a first magnetic field and applying a second magnetic field may be performed simultaneously.

In a further aspect of the present invention, the use of the method for determining the presence and/or amount of magnetic or magnetizable objects in a sample fluid according to embodiments of the invention in molecular diagnostics, biological sample analysis or chemical sample analysis is provided.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

FIG. 1 illustrates the operation principle of a magnetoresistive sensor.

FIG. 2 illustrates a sensor device according to the prior art.

FIG. 3 shows the signal of a GMR sensor element per magnetic or magnetizable object as a function of the x-position of a magnetic or magnetizable object on the sensor surface for the sensor illustrated in FIG. 2.

FIG. 4 illustrates a sensor device according to an embodiment of the invention.

FIG. 5 illustrates a sensor device according to an embodiment of the invention.

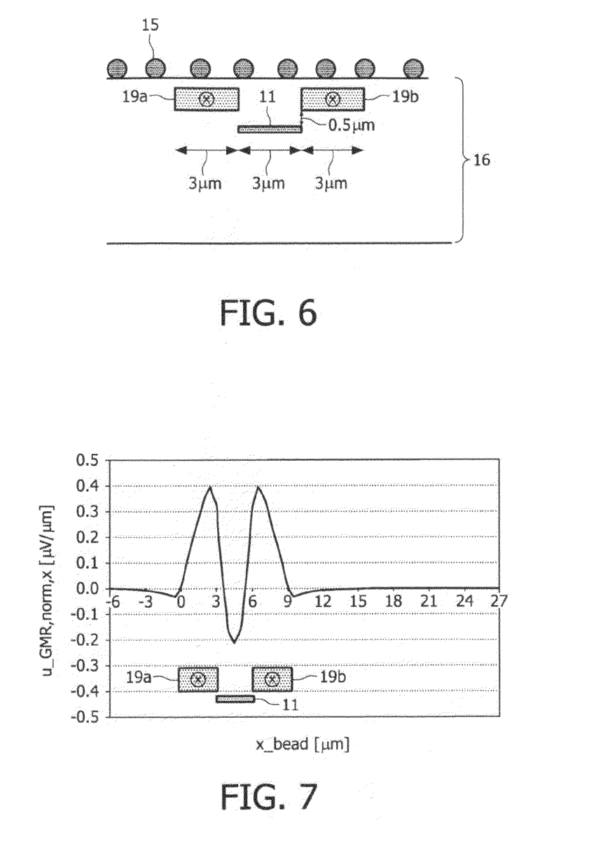

FIG. 6 illustrates a sensor device according to an embodiment of the invention.

FIG. 7 shows the sensitivity of the magnetic sensor device of FIG. 6 as a function of the x-position.

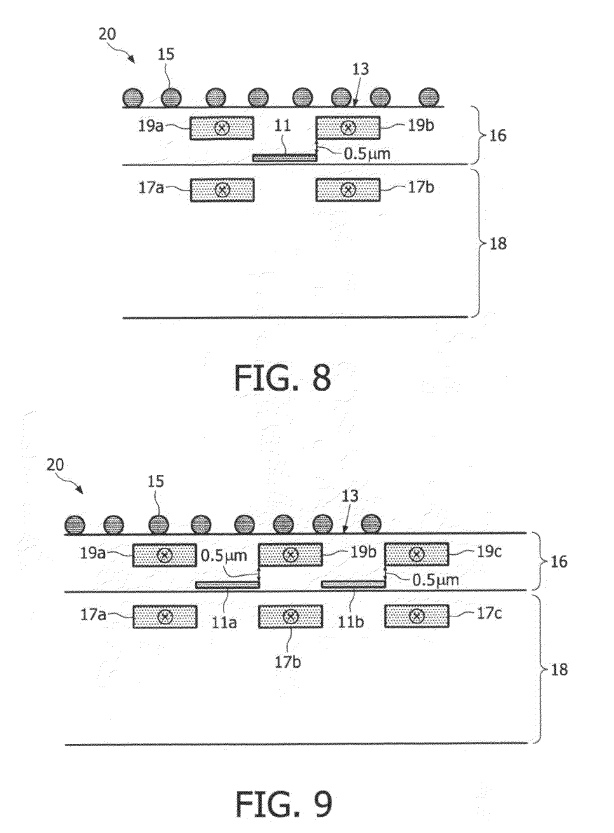

FIG. 8 illustrates a sensor device according to an embodiment of the invention.

FIG. 9 illustrates a sensor device according to an embodiment of the invention.

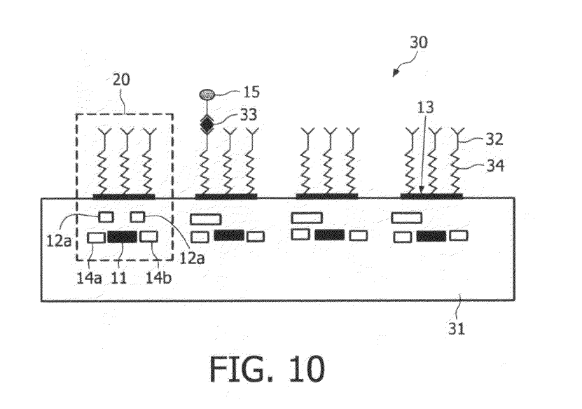

FIG. 10 illustrates a biochip comprising at least one magnetic sensor device according to embodiments of the invention.

In the different figures, the same reference signs refer to the same or analogous elements.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the term under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

The present invention provides a magnetic sensor device and a method for determining the presence and/or amount of magnetic or magnetizable objects in a sample fluid.

In a first aspect the present invention provides a magnetic sensor device comprising at least one sensor element lying in a first plane, a first magnetic field generating means for generating a first magnetic field, the first magnetic field being for attracting magnetic or magnetizable objects toward a sensor surface and a second magnetic field generating means for generating a second magnetic field, the second magnetic field being for magnetizing the magnetic or magnetizable objects or, in other words, for orienting dipolar magnetic fields generated by magnetic moments of magnetic or magnetizable objects in a sensitive direction of the at least one sensor element. The first magnetic field generating means is lying in a second plane different from and substantially parallel to the first plane. According to the present invention, the spacing between the first magnetic field generating means and the sensor element is smaller than the minimum feature size, i.e. the minimal process limit for spacing between features lying in a same plane. With spacing is meant the distance between the first magnetic field generating means and the sensor element defined by projection of the first magnetic field generating means onto the plane of the sensor element according to a direction substantially perpendicular to the first and second plane.

According to most preferred embodiments of the invention, the first magnetic field generating means may be located in between the first plane and the sensor surface. According to these embodiments, the first and second magnetic field generating means are different from each other. An advantage hereof is that actuation or attraction and measurement of magnetizable objects, e.g. magnetic particles, is separated (see further).

The second magnetic field generating means may, according to embodiments, be an on-chip or integrated magnetic field generating means or may, according to other embodiments, be an off-chip or external magnetic field generating means.

The magnetic sensor device according to the present invention can, for example, be used for detecting and/or quantifying target moieties present in a sample fluid and labelled with magnetic and/or magnetizable objects. Target moieties may include molecular species, cell fragments, viruses, etc.

The surface of the magnetic sensor device may be modified by a coating which is designed to attract certain molecules or may be modified by attaching molecules to it, which are suitable to bind the target moieties which are present in the sample fluid. Such moieties or molecules are know to the skilled person and can include complementary DNA, antibodies, antisense RNA, etc. Such molecules may be attached to the surface by means of spacer or linker molecules. The surface of the sensor device can also be provided with molecules in the form of organisms (e.g. viruses or cells) or fractions of organisms (e.g. tissue fractions, cell fractions, membranes). The surface of biological binding can be in direct contact with the sensor chip, but there can also be a gap between the binding surface and the sensor chip. For example, the binding surface can be a material that is separated from the chip, e.g. a porous material. Such a material can be a lateral-flow or a flow-through material, e.g. comprising microchannels in silicon, glass, plastic, etc. The binding surface can be parallel to the surface of the sensor chip. Alternatively, the binding surface can be under an angle with respect to, e.g. perpendicular to, the surface of the sensor chip.

The present invention will further be described by means of a magnetic sensor device based on GMR elements. However, this is not limiting the invention in any way. The present invention may be applied to sensor devices comprising any sensor element suitable for detecting the presence or determining the amount of magnetic or magnetic or magnetizable objects, e.g. magnetic nanoparticles, on or near a sensor surface based on any property of the particles. For example, detection of the nanoparticles may be done by any suitable means, e.g. magnetic methods (magnetoresistive sensor elements, hall sensors, coils), optical methods (e.g. imaging fluorescence, chemiluminescence, absorption, scattering, surface plasmon resonance, Raman, . . . ), sonic detection methods (e.g. surface acoustic wave, bulk acoustic wave, cantilever, quartz crystal, . . . ), electrical detection methods (e.g. conduction, impedance, amperometric, redox cycling), etc.

Furthermore, the present invention will be described by means of the magnetic or magnetizable objects being magnetic particles. The term magnetic particles is to be interpreted broadly such as to include any type of magnetic particles, e.g. ferromagnetic, paramagnetic, superparamagnetic, etc. as well as particles in any form, e.g. magnetic spheres, magnetic rods, a string of magnetic particles, or a composite particle, e.g. a particle containing magnetic as well as optically-active material, or magnetic material inside a non-magnetic matrix. Preferably, the magnetic or magnetizable objects may be ferromagnetic particles which contain small ferromagnetic grains with a fast magnetic relaxation time and which have a low risk of clustering. Again, the wording used is only for the ease of explanation and does not limit the invention in any way.

According to a first embodiment of the present invention, which is illustrated in FIG. 4, the magnetic sensor device 20 comprises at least one GMR sensor element 11, a first magnetic field generating means 12 for attracting magnetic particles to a surface 13 of the magnetic sensor device 20 and second magnetic field generating means 14 for magnetizing the magnetic particles or, in other words, for orienting dipolar magnetic fields generated by magnetic moments of magnetic or magnetizable objects in a sensitive direction of the at least one sensor element. The second magnetic field generating means 14 for magnetizing magnetic particles may, according to the example given in FIG. 4, be implemented by a first and second current wire 14a, 14b.

According to the first embodiment, the GMR sensor element 11 and the second magnetic field generating means 14 may be lying in a first plane and the surface 13 of the sensor device 20 may be lying in second plane, the first and second plane being different from and substantially parallel to each other. The first magnetic field generating means 12 may be lying in a third plane substantially parallel to the first and second plane. Most preferably and as illustrated in FIG. 4 the first magnetic field generating means 12 may be located in between the first and second plane. The first magnetic field generating means 12 may, according to the example given in FIG. 4, be formed by first and second current wire 12a, 12b. The first current wire 12a may be positioned at a first side of the GMR sensor element 11 and the second current wire 12b may be positioned at a second side of the GMR sensor element 11, the first and second side being opposite to each other.

According to preferred embodiments of the invention and as illustrated in FIG. 4, each of the first and second current wire 12a, 12b may show an overlap “O” with the GMR sensor element 11, the overlap “O” being defined by projection of the current wires 12a, 12b onto the GMR sensor element 11 according to a direction substantially perpendicular to the first, second and third planes. The overlap “O” may preferably be between 0 μm and 1 μm or between 0 μm and 0.5 μm.

According to other embodiments of the invention, the current wires 12a, 12b may show no overlap “O” with the GMR sensor element 11. In these cases, the spacing between the current wires 12a, 12b and the GMR sensor element 11 may preferably be between 0 and the minimum feature size, i.e. the minimal process limit for spacing between features lying in a same plane, which, according to current techniques may be about 2 μm.

The spacing is determined by the distance d between the current wires 12a, 12b and the GMR sensor element 11 which is defined by projection of the current wires 12a, 12b onto the plane of the GMR sensor element 11 according to a direction substantially perpendicular to the first, second and third planes.

Hence, in general, according to the present invention, the spacing between the first magnetic field generating means, in the example given current wires 12a, 12, and the sensor element, in the example given the GMR sensor element 11, is smaller than the minimum feature size, i.e. minimal process limit for spacing between features lying in a same plane. According to conventional process methods for the manufacturing of sensor devices, a minimal spacing of about 2 μm may be obtained. Preferably, the spacing between the first magnetic field generating means, in the example given current wires 12a, 12, and the sensor element, in the example given the GMR sensor element 11, is as small as possible and may preferably be smaller than 2 μm and most preferably smaller than 1 μm.

According to the present invention, the first and second magnetic field generating means 12, 14 may be activated or driven simultaneously or separately.

When the first magnetic field generating means, in the example given current wires 12a, 12b, are driven, a first magnetic field is generated and magnetic particles are attracted toward the sensor surface 13 by the first magnetic field. At least some of the magnetic particles which are attracted towards the sensor surface 13 may bind to binding sites present on the sensor surface 13. In the ‘bind’ phase, the magnetic particles are brought even closer to the binding surface in a way to optimise the occurrence of desired (bio)chemical binding to a capture or binding area on the sensor surface 13, i.e. the area where there is a high detection sensitivity by the at least one sensor element 11, e.g. magnetic sensors, and a high biological specificity of binding. For optimising the bind process, there is a need to increase the contact efficiency (to maximise the rate of specific biological binding when the bead is close to the binding surface) as well as the contact time (the total time that individual beads are in contact with the binding surface).

When the second magnetic field generating means, in the example given current wires 14a, 14b are driven, a current flowing through the current wires 14a, 14b generates a second magnetic field which magnetizes the magnetic particles present at the sensor surface 13. The magnetic particles hereby develop a magnetic moment m. The magnetic moment m then generates dipolar magnetic fields, which have in-plane magnetic field components at the location of the sensor element 11. Thus, the magnetic particles deflect the second magnetic field induced by the current through the second magnetic field generating means 14, resulting in the magnetic field component in the sensitive x-direction of the sensor element 11. In that way, magnetic particles can be detected and/or quantified.

Because of the location of the current wires 12a, 12b, or more in general because of the location of the first magnetic field generating means 12, by passing a DC and/or an AC current through at least one of the current wires 12a, 12b, magnetic particles may be attracted to the most sensitive areas at the surface 23 of the magnetic sensor device 20, which, as illustrated in FIG. 3, are located at the edges of the GMR sensor element 11 and between the current wires 12a, 12b and the GMR sensor element 11.

An advantage hereof is that the first magnetic field generating means 12 for attracting magnetic particles to the sensor surface 13 is still electrically isolated from the sample fluid, and thus electrochemical reactions can be prevented, but provides a possibility to attract magnetic particles to the most sensitive locations of the magnetic sensor device 20. Hence, an increase of sensitivity of the magnetic sensor device 20 may be obtained.

Because magnetic particles are attracted toward the most sensitive areas on the magnetic sensor device 20, higher average signals of between 4 and 6 nV/particle and less position dependent variation of the resulting signal from different particles can be obtained, and thus low concentrations of magnetic particles may be measured.

Another advantage according to the magnetic device 20 according to the first embodiment of the invention is that attraction and detection of magnetic particles may be done simultaneously or separately.

When attraction and detection of magnetic particles is performed simultaneously, the first magnetic field generating means 12 may generate a first magnetic field with a first frequency and/or phase for attracting magnetic particles toward the sensor surface 13 and the second magnetic field generating means 14 may generate a second magnetic field with a second frequency and/or phase for magnetising magnetic particles which have bonded to the sensor surface 13, the second frequency being different from the first frequency and/or the second phase being different from the first phase. By measuring a resulting magnetic field in a sensitive layer of the GMR sensor element 11 and discriminating, based on the frequencies and/or phases of the measured signal, in the resulting magnetic field between a first component emanating from the first magnetic field and a second component emanating from the second magnetic field, the presence and/or amount of magnetic particles at the sensor surface 13 may be accurately determined from the second component.

According to a second embodiment of the present invention, the first and second magnetic field generating means 12, 14 may be joined into one magnetic field generating means, which in the further description will be referred to as combined magnetic field generating means 19. In other words, the combined magnetic field generating means 19 may have both the function of attracting magnetic particles toward the sensor surface 13 and the function of magnetizing magnetic particles which are bound to the sensor surface 13. Again, the GMR sensor element 11 is lying in a first plane and the combined magnetic field generating means 19 is lying in a second plane, the second plane being substantially parallel to and different from the first plane. Most preferably, the combined magnetic field generating means 19 may be located in between the first plane and the sensor surface 13. The combined magnetic field generating means may be implemented by current wires 19a, 19b as illustrated in FIGS. 5 and 6 which illustrate a magnetic sensor device 20 according to the second embodiment.

The combined magnetic field generating means may be implemented by current wires 19a, 19b. In the example given in FIG. 5, an overlap “O” exists between the current wires 19a, 19b and the GMR sensor element 11, the overlap “O” being defined by projection of the current wires 19a, 19b onto the GMR sensor element 11 according to a direction substantially perpendicular to the first, second and third planes. The overlap “O” may preferably be between 0 μm and 1 μm or between 0 μm and 0.5 μm.

According to other embodiments of the invention, and as illustrated in FIG. 6, the current wires 19a, 19b may show no overlap “O” with the GMR sensor element 11. In these cases, the spacing between the current wires 19a, 19b and the GMR sensor element 11 may preferably be between 0 (see FIG. 6) and the minimum feature size, i.e. the minimal process limit for spacing between features lying in a same plane. The spacing is determined by the distance d between the current wires 19a, 19b and the GMR sensor element 11 which is defined by projection of the current wires 19a, 19b onto the plane of the GMR sensor element 11 according to a direction substantially perpendicular to the first, second and third planes.

Hence, in general, according to the present invention, the spacing between the combined magnetic field generating means, in the example given current wires 19a, 19b, and the sensor element, in the example given the GMR sensor element 11, is smaller than the minimum feature size, i.e. smaller than the minimal process limit for spacing between features lying in a same plane. According to conventional process methods for the manufacturing of sensor devices, a minimal spacing of about 2 μm may be obtained. Preferably, the spacing between the combined magnetic field generating means, in the example given current wires 19a, 19b, and the sensor element, in the example given the GMR sensor element 11, is as small as possible and may preferably be smaller than 2 μm and most preferably smaller than 1 μm.

FIG. 7 illustrates the sensor sensitivity for a magnetic sensor device 20 according to the second embodiment of the invention as a function of the x-position of the magnetic particles 15 at the sensor surface 13. Again, because of the location of the current wires 19a, 19b, or more in general because of the location of the combined magnetic field generating means 19, by passing a DC and/or an AC current through at least one of the current wires 19a, 19b, magnetic particles 15 may be attracted to the most sensitive areas at the surface 13 of the magnetic sensor device 20, which, as illustrated in FIG. 3, are located at the edges of the GMR sensor element 11 and between the current wires 19a, 19b and the GMR sensor element 11. The same field generated by the DC and/or AC current through the current wires 19a, 19b may be used to detect and/or quantify the magnetic particles 15 in a same way as described in the first embodiment.

During attraction of the magnetic particles 15 toward the sensor surface 13, large magnetic fields may be generated by the current wires 19a, 19b which have components in the sensitive direction of the GMR sensor element 11. Therefore, preferably anti-parallel currents may be sent through the current wires 19a, 19b in order to cancel the magnetic field component in the sensitive direction of the GMR sensor element 11 during attraction of the magnetic particles 15.

An advantage hereof is that the first magnetic field generating means 12 for attracting magnetic particles 15 to the sensor surface 13 is still electrically isolated from the sample fluid but provides a possibility to attract magnetic particles 15 to the most sensitive locations of the magnetic sensor device 20. Hence, an increase of sensitivity of the magnetic sensor device 20 may be obtained.

A further advantage of the magnetic sensor device 20 according to the second embodiment of the present invention is that, when the magnetic sensor device 20 comprises more than one GMR sensor element 11, the different GMR sensor elements can be placed close to each other, the only restriction being the minimum feature size or minimal process limit for spacing between features in a same plane, which for current processes is about 2 μm. In that way it is possible to provide more sensor elements 11 on one substrate compared with prior art devices and thus it is possible to provide the magnetic sensor device 20 with more sensitive area which again increases the sensitivity of the magnetic sensor device 20.

The magnetic sensor device 20 according to the second embodiment, however, can have a disadvantage of showing magnetic field cross-talk between the current wires 19a, 19b and the GMR sensor element 11, which can locally overload the GMR sensor element 11.

Therefore, according to a third embodiment of the present invention, the magnetic sensor device 20 may furthermore comprise a third magnetic field generating means 17 located in a fourth plane, different from and substantially parallel to the first, second and third plane and located such that the distance between the sensor surface 13 and the fourth plane is larger than the distance between the sensor surface 13 and the first plane. According to this embodiment, the magnetic sensor device 20 may comprise two parts, i.e. a first part which comprises the combined magnetic field generating means implemented by current wires 19a, 19b and the GMR sensor element 11 (see FIG. 8) or the first and second magnetic field generating means 12, 14 and the GMR sensor element 11 and which may be called sensor layer 16, and a second part which comprises the third magnetic field generating means 17 and which may be called signal processing layer 18.

The third magnetic field generating means 17 may be implemented by current wires 17a, 17b. The third magnetic field generating means 17 may be used for compensating for the magnetic cross-talk generated by the current wires 19a, 19b in the GMR sensor element 11. Preferably, the distance between the plane comprising, in the example given, the combined magnetic field generating means 19 and the plane comprising the GMR sensor element 11 may be equal to the distance between the plane comprising the third magnetic field generating means 17 and the plane comprising the GMR sensor element 11. In this case, magnetic cross-talk may be cancelled by sending a same current through the current wires 17a, 17b forming the third magnetic field generating means as through the current wires 19a, 19b forming the combined magnetic field generating means.

However, according to other embodiments, the distance between the plane comprising, in the example given, the combined magnetic field generating means 19 and the plane comprising the GMR sensor element 11 may be different from, i.e. smaller or larger than, the distance between the plane comprising the third magnetic field generating means 17 and the plane comprising the GMR sensor element 11. In this case, lower or higher currents may be sent through the current wires 11a, 17b forming the third magnetic field generating means than through the current wires 19a, 19b forming the combined magnetic field generating means.

According to the third embodiment of the invention, the magnetic cross-talk may be suppressed at every position in the sensitive layer of the GMR sensor element 11.

In the device 20 according to the third embodiment, the magnetic field above the sensor may have about 1.5 times increased due to the contribution of the third magnetic field generating means 17.

Again, when the magnetic sensor device 20 comprises more than one GMR sensor element 11, the different GMR sensor elements 11 can be placed close to each other, the only restriction being the minimum feature size or the minimal process limit for spacing between features in a same plane, which for current processes is about 2 μm. In that way it is possible to provide more sensor elements 11 on one sensor chip compared with prior art devices and thus it is possible to provide the magnetic sensor device 20 with more sensitive area which again increases the sensitivity of the magnetic sensor device 20. This is illustrated in FIG. 9.

The present invention also provides, in a second aspect, a method for determining the presence and/or amount of magnetic or magnetizable objects 15 in a sample fluid by using the magnetic sensor device 20 according to the above described embodiments.

In a first step, the method comprises providing the sample fluid to the sensor surface 13. Next, a first magnetic field generated by the first magnetic field generating means 12 is applied for attracting the magnetic particles 15 toward the sensor surface 13, the first magnetic field having a first frequency and/or a first phase. Then, a second magnetic field is applied for magnetizing the magnetic particles 15, the second magnetic field having a second frequency different from the first frequency and/or a second phase different from the first phase. In a further step, a magnetic field in a sensitive layer of the at least one sensor element 11 is measured, the magnetic field having a first component emanating from the first magnetic field and a second component emanating from the second magnetic field. Only the component coming from the second magnetic field, i.e. from the magnetic field for magnetizing the magnetic particles 15, will give information about the presence and/or amount of magnetic particles 15 present at the sensor surface 13. Therefore, a next step in the method according to the present invention is in the measured magnetic field discriminating, based on the frequencies and/or phases in the measured signal, between the first component emanating from the first magnetic field and the second component emanating from the second magnetic field. In a last step, the presence and/or amount of magnetic particles 15 may be determined from the second component.

For example, attraction of magnetic particles 15 may be performed with a first magnetic field having a frequency of, for example, 2 MHz, and magnetizing the magnetic particles 15 may be performed with a magnetic field having a frequency of, for example, 1 MHz. After measuring the magnetic field in the sensitive layer of the GMR sensor element 11, the component at 2 MHZ may be removed from resulting signal by, for example, filtering. In that way, the obtained signal is representative for the presence and/or amount of magnetic particles 15 present at the sensor surface 13.

According to embodiments of the invention, the first magnetic field may have a first phase and the second magnetic field may have a second phase different from the first phase. In these cases, the step of discriminating between the first component emanating from the first magnetic field and the second component emanating from the second magnetic field may be based on phases.

For example, the first phase of the first magnetic field may be shifted over e.g. 90 degrees with respect to the second phase of the second magnetic field by e.g. in plane or quadrature demodulation.

Preferably, applying the first and second magnetic field may be performed simultaneously.

The method according to the present invention may be used in molecular diagnostics, biological sample analysis or chemical sample analysis.

In another aspect, the present invention also provides a biochip 30 comprising at least one magnetic sensor device 20 according to embodiments of the present invention. FIG. 10 illustrates a biochip 30 according to an embodiment of the present invention. The biochip 30 may comprise at least one magnetic sensor device 20 according to embodiments of the present invention integrated in a substrate 31. The term “substrate” may include any underlying material or materials that may be used, or upon which a device, a circuit or an epitaxial layer may be formed. The term “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include, for example, an insulating layer such as a SiO₂ or an Si₃N₄ layer in addition to a semiconductor substrate portion. Thus the term “substrate” also includes glass, plastic, ceramic, silicon-on-glass, silicon-on-sapphire substrates. The term “substrate” is thus used to define generally the elements for layers that underlie a layer or portions of interest. Also the “substrate” may be any other base on which a layer is formed, for example a glass or metal layer.

According to embodiments of the invention a single magnetic sensor device 20 or a multiple of magnetic sensor devices 20 may be integrated on the same substrate 31 to form the biochip 30.

According to the present example, the first magnetic field generating means may comprise a first and a second electrical conductor, e.g. implemented by a first and second current conducting wire 14a and 14b. Also other means instead of current conducting wires 14a, 14b may be applied to generate the external magnetic field. Furthermore, the first magnetic field generating means may also comprise another number of electrical conductors.

In each magnetic sensor device 20 at least one sensor element 11, for example a GMR element, may be integrated in the substrate 31 to read out the information gathered by the biochip 30, thus for example to read out the presence or absence of target particles 33 via magnetic or magnetizable objects 15, e.g. magnetic nanoparticles, attached to the target particles 33, thereby determining or estimating an areal density of the target particles 33. The magnetic or magnetizable objects 15, e.g. magnetic particles, are preferably implemented by so called superparamagnetic beads. Binding sites 32 which are able to selectively bind a target molecule 33 are attached on a probe element 34. The probe element 34 is attached on top of the substrate 31 or on top of a surface layer, e.g. a gold layer, that is applied on top of the substrate 31 to facilitate binding of the probe element 34 to the sensor surface 13.

According to the present invention, each magnetic sensor device 20 may comprise a further magnetic field generating means, which may be implemented by current wires 12a, 12b.

The functioning of the biochip 30, and thus also of the magnetic sensor device 20, will be explained hereinafter. Each probe element 34 may be provided with binding sites 32 of a certain type, for binding pre-determined target molecules 33. A target sample, comprising target molecules 33 to be detected, may be presented to or passed over the probe elements 34 of the biochip 30, and if the binding sites 32 and the target molecules 33 match, they bind to each other. The superparamagnetic beads 15, or more generally the magnetic or magnetizable objects, may be directly or indirectly coupled to the target molecules 33. The magnetic or magnetizable objects, e.g. superparamagnetic beads 15, allow to read out the information gathered by the biochip 30.

In addition to molecular assays, also larger moieties can be detected, e.g. cells, viruses, or fractions of cells or viruses, tissue extract, etc. Detection can occur with or without scanning of the sensor element with respect to the biosensor surface.

Measurement data can be derived as an end-point measurement, as well as by recording signals kinetically or intermittently.

The magnetic or magnetizable objects 15, e.g. magnetic particles, can be detected directly by the sensing method. As well, the magnetic or magnetizable objects 15, e.g. magnetic particles, can be further processed prior to detection. An example of further processing is that materials are added or that the (bio)chemical or physical properties of the magnetic or magnetizable objects 15, e.g. magnetic particles, are modified to facilitate detection.

The magnetic sensor device 20 and biochip 30 according to embodiments of the present invention can be used with several biochemical assay types, e.g. binding/unbinding assay, sandwich assay, competition assay, displacement assay, enzymatic assay, etc.

The magnetic sensor device 20 and biochip 30 according to embodiments of this invention are suitable for sensor multiplexing (i.e. the parallel use of different sensors and sensor surfaces), label multiplexing (i.e. the parallel use of different types of labels or magnetic or magnetizable objects) and chamber multiplexing (i.e. the parallel use of different reaction chambers).

The magnetic sensor device 20 and biochip 30 according to embodiments of the present invention can be used as rapid, robust, and easy to use point-of-care biosensors for small sample volumes. The reaction chamber can be a disposable item to be used with a compact reader, containing the one or more magnetic field generating means and one or more detection means. Also, the device 20 and biochip 30 according to the present invention can be used in automated high-throughput testing. In this case, the reaction chamber may, for example, be a well plate or cuvette, fitting into an automated instrument.

Although described herein as magnetic sensor device, the sensing or detection of the presence of magnetic or magnetizable objects 15 can be done in many ways. Therefore, the sensor element 11 can be any suitable sensor element 11 to detect the presence of magnetic or magnetizable objects 15 or magnetic particles on or near to a sensor surface, based on any property of the particles, e.g. it can detect via magnetic methods, e.g. magnetoresistive, Hall, coils. The sensor element 11 can detect via optical methods, for example imaging, fluorescence, chemiluminescence, absorption, scattering, surface plasmon resonance, Raman spectroscopy etc. Further, the sensor element 11 can detect via sonic detection, for example surface acoustic wave, bulk acoustic wave, cantilever deflections influenced by the biochemical binding process, quartz crystal etc. Further, the sensor element 11 can detect via electrical detection, for example conduction, impedance, amperometric, redox cycling, etc.

It is to be understood that although preferred embodiments, specific constructions and configurations, as well as materials, have been discussed herein for devices according to the present invention, various changes or modifications in form and detail may be made without departing from the scope and spirit of this invention.

1. Magnetic sensor device (20) having a surface (13) and comprising:
at least one sensor element (11) for sensing the presence of magnetic or magnetizable objects (15), the at least one sensor element (11) lying in a first plane,
first magnetic field generating means (12) for generating a first magnetic field, the first magnetic field being for attracting magnetic or magnetizable objects (15) toward the sensor surface (13), and
second magnetic field generating means (14) for generating a second magnetic field, the second magnetic field being for magnetizing the magnetic or magnetizable objects (13),
the first magnetic field generating means (12) lying in a second plane different from and substantially parallel to the first plane, wherein the spacing between the first magnetic field generating means (12) and the sensor element (11) is smaller than 2 micron down to optionally overlapping.

2. Magnetic sensor device (20) according to claim 1, wherein the first magnetic field generating means (12) is located in between the first plane and the sensor surface (13).

3. Magnetic sensor device (20) according to claim 1, wherein the first magnetic field generating means (12) has an overlap with the sensor element (11), the overlap being defined by the projection of the first magnetic field generating means (12) onto the sensor element (11) in a direction substantially perpendicular to the first and second plane.

4. Magnetic sensor device (20) according to claim 1, wherein the first magnetic field generating means (12) and the second magnetic field generating means (14) are joined in a same combined magnetic field generating means (19).

5. Magnetic sensor device (20) according to claim 1, wherein the second magnetic field generating means (14) lies in the same first plane as the at least one sensor element (11).

6. Magnetic sensor device (20) according to claim 1, wherein the device (20) furthermore comprises a third magnetic field generating means (17) lying in a third plane substantially parallel to the first and second plane, the third plane being located such that the distance between the sensor surface (13) and the third plane is larger than the distance between the sensor surface (13) and the second plane.

7. Magnetic sensor device (20) according to claim 1, wherein the second magnetic field generating means (14) is an on-chip magnetic field generating means.

8. Magnetic sensor device (20) according to claim 1, wherein the second magnetic field generating means (14) is an off-chip magnetic field generating means.

9. A biochip (30) comprising at least one magnetic sensor device (20) according to claim 1.

10. Use of the magnetic sensor device (20) according to claim 1 in molecular diagnostics, biological sample analysis or chemical sample analysis.

11. Use of the biochip (30) according to claim 9 in molecular diagnostics, biological sample analysis or chemical sample analysis.

12. Method for determining the presence and/or amount of magnetic or magnetizable objects (15) in a sample fluid, the method comprising:
providing the sample fluid to a surface (13) of a magnetic sensor device (20) according to claim 1,
applying a first magnetic field having a first frequency and a first phase for attracting the magnetic or magnetizable objects (15) toward the sensor surface (13),
applying a second magnetic field having a second frequency and a second phase for magnetizing the magnetic or magnetizable objects (15), the second frequency being different from the first frequency or the second phase being different from the first phase,
measuring a magnetic field in a sensitive layer of the at least one sensor element (11),
in the measured magnetic field discriminating between a first component emanating from the first magnetic field and a second component emanating from the second magnetic field, and
determining the presence and/or amount of magnetic or magnetizable objects (15) from the second component.

13. Method according to claim 12, wherein applying a first magnetic field and applying a second magnetic field is performed simultaneously.

14. Use of the method according to claim 12 in molecular diagnostics, biological sample analysis or chemical sample analysis.
